(19) United States
(12) Patent Application Publication
(10) Pub. No.: US 2025/0234504 A1
(43) Pub. Date: Jul. 17, 2025

(54) MEMORY, DYNAMIC RANDOM ACCESS MEMORY, AND ELECTRONIC DEVICE

(71) Applicant: BEIJING SUPERSTRING ACADEMY OF MEMORY TECHNOLOGY, Beijing (CN)

(72) Inventors: Xiangsheng Wang, Beijing (CN); Guilei Wang, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 18/692,092

(22) PCT Filed: Sep. 23, 2022
(86) PCT No.: PCT/CN2022/121069

§ 371 Date: Mar. 14, 2024

(30) Foreign Application Priority Data
May 17, 2022 (CN) 202210542088.4

(51) Int. Cl. H10B 12/00

(52) U.S. Cl. CPC H10B 12/30; H10B 12/03; H10B 12/05

(57) ABSTRACT

A memory, a dynamic random access memory, and an electronic device are provided. The memory may be a 3D memory, and includes: a substrate; a plurality of memory cell columns distributed in a first direction perpendicular to the substrate, wherein each memory cell column includes a plurality of memory cell stacked in the first direction; each memory cell includes a transistor and a capacitor; the transistor comprises a semiconductor layer and a gate, and the semiconductor layer includes a first semiconductor layer and a cylindrical second semiconductor layer arranged on the sidewall of the first semiconductor layer. Other structures of the transistor and capacitor have the same definition as those in the description.

### CROSS-REFERENCE TO RELATED APPLICATIONS

The present application is a U.S. National Phase Entry of International Application PCT/CN2022/121069 having an international filing date of Sep. 23, 2022, which claims priority to Chinese Patent Application No. 202210542088.4 filed to the CNIPA on May 17, 2022 and entitled “Semiconductor equipment structure and manufacturing method thereof, DRAM and Electronic Device”, and the contents disclosed in the above-mentioned applications are incorporated into the present disclosure by reference.

### TECHNICAL FIELD

The present disclosure relates to the field of semiconductor equipment, in particular to a memory, a dynamic random access memory and an electronic device.

### BACKGROUND

A dynamic random access memory (DRAM) is a common system memory, and its annual output value accounts for about 30% of the whole semiconductor industry. At present, a structure having a transistor paired with a capacitor is widely used as a DRAM cell in the industry. The combination of 1 TIC elements makes the storage bits of the DRAM become the electronic elements with the highest density and the lowest manufacturing costs per unit, which plays an irreplaceable role in computer access equipment. With the rapid development of semiconductor technology, DRAM elements are rapidly developing in the direction of high density and high quality. In order to rapidly improve the integration and scalability of the memory, the integration density of semiconductor devices has been increasing, and the design size standard of semiconductor devices has also been decreasing

### SUMMARY

The following is a summary of the subject matters described in detail in this document.

The summary is not intended to limit the scope of protection of the present disclosure.

Embodiments of the present disclosure provide a memory comprising:
a substrate;
a plurality of memory cell columns distributed in a first direction perpendicular to the substrate, each of the memory cell columns comprising a plurality of memory cells disposed and stacked along the first direction, different memory cell columns being arranged on the substrate along a second direction and a third direction to form an array; the second direction and the third direction being intersected and the formed plane being parallel to the main plane of the substrate;
the memory cell comprising a transistor and a capacitor disposed in sequence along the second direction, the transistor comprising a semiconductor layer and a gate, the semiconductor layer extending as a strip structure along the second direction, the strip structure having sidewalls and both ends, and the sidewall in the second direction comprising a source region, a channel region and a drain region, the source region and the drain region being adjacent to two ends_of the semiconductor layer, respectively, the channel region being located between the source region and the drain region, the semiconductor layer comprising a first semiconductor layer and a cylindrical second semiconductor layer disposed on the sidewalls of the first semiconductor layer, and the gate encircling the sidewalls of the second semiconductor layer in the channel region; an electrode and a dielectric layer of the capacitor encircling the sidewall of a second semiconductor layer in the drain region.

In an embodiment of the present disclosure, the memory may further comprise multiple bit lines extending along the first direction, two adjacent memory cells along the second direction being in a mirror image distribution, source regions of the transistors of the two adjacent memory cells being connected to one common bit line.

In an embodiment of the present disclosure, the memory may further comprise multiple word lines extending along the third direction and arranged at intervals in the first direction, wherein the substrate is provided with one memory cell column in the third direction, and each word line is formed by connecting the gates in the transistors of one memory cell of one memory cell column arranged along the third direction.

In the embodiment of the present disclosure, multiple word lines arranged at intervals in the first direction have different lengths and form a staircase shape.

In an embodiment of the present disclosure, a material for the word line comprises at least one of indium and tin.

In an embodiment of the present disclosure, a material for the first semiconductor layer is selected from any one or more of Group IVA semiconductor materials, for example, the material for the first semiconductor layer is single-crystal silicon.

In an embodiment of the present disclosure, the material for the second semiconductor layer may be a metal oxide semiconductor material, the metal in the metal oxide comprising at least one of indium, zinc, tungsten, tin, titanium, zirconium, hafnium, and gallium.

In an embodiment of the present disclosure, the memory cell column further comprises an interlayer isolation layer disposed between the gates of the transistors of two adjacent memory cells in the memory cell column to isolate the gates of the transistors of the two adjacent memory cells.

In an embodiment of the present disclosure, the memory may further comprise one or more memory cell isolation pillars extending along the first direction, and one memory cell isolation pillar being provided every two memory cell columns in the second direction.

In an embodiment of the present disclosure, a material for the memory cell isolation pillar is silicon oxide.

In an embodiment of the present disclosure, the memory may further comprise an internal support layer disposed between two adjacent semiconductor layers along the first direction and configured to provide support to the semiconductor layers.

In an embodiment of the present disclosure, the internal support layer is located on a sidewall of the memory cell isolation pillar.

In an embodiment of the present disclosure, a material for the internal support layer is silicon nitride (SiN).

Embodiments of the present disclosure also provide a memory comprising:

multiple repeating units distributed in an array, and every two adjacent repeating units being isolated by an isolation pillar; wherein, the repeating unit comprises at least one layer of memory cell, and each layer of the repeating unit comprises a first memory cell and a second memory cell located between the two isolation pillars; wherein the two memory cells comprise a first transistor and a second transistor;
one or a plurality of transversely extending semiconductor pillars being disposed between the two isolation pillars, and the plurality of transversely extending semiconductor pillars being distributed as intervals along a direction perpendicular to the substrate;
the semiconductor pillar having sidewalls and two ends positioned in the isolation pillar such that the semiconductor pillar is supported by the isolation pillar;
a first ring-shaped semiconductor layer and a second ring-shaped semiconductor layer being distributed at intervals in the transverse direction in different regions of the sidewalls of the semiconductor pillar; the first ring-shaped semiconductor layer and the second ring-shaped semiconductor layer being wrapped with a first gate and a second gate disposed at intervals, respectively, wherein the first gate is insulated from the first ring-shaped semiconductor layer through an insulating layer, and the second gate is insulated from the second ring-shaped semiconductor layer through the insulating layer;
wherein, the memory further comprises a first capacitor and a second capacitor transversely distributed at intervals in different regions of the sidewalls of the semiconductor pillar; the first memory cell comprises the first capacitor and the first transistor, and the second memory cell comprises the second capacitor and the second transistor;
the first capacitance electrode of the first capacitor and the second capacitance electrode of the second capacitor wrap different regions of the sidewalls of the semiconductor pillar, respectively;
wherein the first capacitor, the first transistor, the second transistor and the second capacitor are transversely distributed at intervals in sequence.

Embodiments of the present disclosure also provide a dynamic random access memory comprising a memory as described above.

The disclosure also provides an electronic device comprising a dynamic random access memory as described above.

In an embodiment of the present disclosure, the electronic device may comprise a storage apparatus, a smart phone, a computer, a tablet computer, an artificial intelligence device, a wearable device, or a mobile power supply.

Other features and advantages of the present disclosure will be set forth in the following specification, and moreover, partially become apparent from the specification, or are understood by implementing the present disclosure. Other advantages of the present disclosure may be realized and attained by the schemes described in the specification as well as in the appended drawings.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1A is a schematic diagram of a main cross-sectional structure of a 3D memory according to an exemplary embodiment of the present disclosure in one direction;

FIG. 1B is an enlarged diagram of a transistor of the 3D memory shown in FIG. 1A;

FIG. 1C is an enlarged diagram of a capacitor of the 3D memory shown in FIG. 1A;

FIG. 1D is a schematic diagram of a top structure of the 3D memory shown in FIG. 1A;

FIG. 2 is a distribution state diagram of multiple word lines arranged at intervals along the first direction in a side view direction of a 3D memory according to another exemplary embodiment of the present disclosure;

FIG. 3A is a schematic view of a main cross-sectional structure of a 3D memory according to another exemplary embodiment of the present disclosure in one direction;

FIG. 3B is a schematic diagram of a top structure of the 3D memory shown in FIG. 3A;

FIG. 4 is a process flow diagram of a manufacturing method of a memory according to an embodiment of the present disclosure;

FIG. 5A is a schematic diagram of a main cross-sectional structure of an intermediate product obtained by an intermediate step of a manufacturing method of a memory according to an exemplary embodiment of the present disclosure;

FIG. 5B is a schematic diagram of a top structure of an intermediate product obtained by an intermediate step of a manufacturing method of a memory according to an exemplary embodiment of the present disclosure;

FIG. 6A is a schematic diagram of a main cross-sectional structure of an intermediate product obtained by an intermediate step of a manufacturing method of a memory according to an exemplary embodiment of the present disclosure;

FIG. 6B is a schematic diagram of a top structure of an intermediate product obtained by an intermediate step of a manufacturing method of a memory according to an exemplary embodiment of the present disclosure;

FIG. 7A is a schematic diagram of a main cross-sectional structure of an intermediate product obtained by an intermediate step of a manufacturing method of a memory according to an exemplary embodiment of the present disclosure;

FIG. 7B is a schematic diagram of a top structure of an intermediate product obtained by an intermediate step of a manufacturing method of a memory according to an exemplary embodiment of the present disclosure;

FIG. 8A is a schematic diagram of a main cross-sectional structure of an intermediate product obtained by an intermediate step of a manufacturing method of a memory according to an exemplary embodiment of the present disclosure;

FIG. 8B is a schematic diagram of a top structure of an intermediate product obtained by an intermediate step of a manufacturing method of a memory according to an exemplary embodiment of the present disclosure;

FIG. 9A is a schematic diagram of a main cross-sectional structure and a schematic diagram of a top structure of an intermediate product obtained by an intermediate step of a manufacturing method of a memory according to an exemplary embodiment of the present disclosure;

FIG. 9B is a schematic diagram of a main cross-sectional structure and a schematic diagram of a top structure of an intermediate product obtained by an intermediate step of a manufacturing method of a memory according to an exemplary embodiment of the present disclosure;

The meanings of the reference signs are:

100-substrate; 200-memory cell column; 300-bit line; 300′-bit line trench; 400-word line; 500-memory cell isolation pillar; 500′-memory cell isolation groove; 600-internal support layer; 600′-internal support groove; 700-isolation material; 800-sacrificial layer; 1-memory cell; l′-memory cell region; 10-transistor; 11-semiconductor layer; 111-source region; 112-channel region; 113-drain region; 114-first semiconductor layer; 114′-first initial semiconductor layer; 115-second semiconductor layer; 12-gate; 20-capacitor; 21-first electrode plate; 22-second electrode plate; 23-dielectric layer; 2-interlayer isolation layer.

### DETAILED DESCRIPTION

In order to make the purposes, technical aspects and advantages of the present disclosure clearer, embodiments of the present disclosure will be described in detail below in conjunction with the accompanying drawings. It should be noted that the embodiments in the present disclosure and the features in the embodiments can be arbitrarily combined with each other without conflict.

In the description of the present disclosure, ordinal numbers such as “first”, “second” and the like are set to avoid confusion of constituent elements and are not intended to be quantitatively limited.

Embodiments of the present disclosure provide a 3D memory.

The 3D memory provided by the embodiments of the present disclosure comprises:
a substrate;
multiple memory cell columns distributed in a first direction perpendicular to the substrate, each of the memory cell columns comprising a plurality of memory cells disposed and stacked along the first direction, different memory cell columns being arranged on the substrate along a second direction and a third direction to form an array; the second direction and the third direction being intersected and the formed plane being parallel to the main plane of the substrate;
the memory cell comprising a transistor and a capacitor disposed in sequence along the second direction, the transistor comprising a semiconductor layer and a gate, the semiconductor layer extending as a strip structure along the second direction, the strip structure having sidewalls and both ends, and the sidewall in the second direction comprising a source region, a channel region and a drain region, the source region and the drain region being adjacent to two ends of the semiconductor layer, respectively, the channel region being located between the source region and the drain region, the semiconductor layer comprising a first semiconductor layer and a cylindrical second semiconductor layer disposed on the sidewalls of the first semiconductor layer, and the gate encircling the sidewalls of the second semiconductor layer in the channel region; an electrode and a dielectric layer of the capacitor encircling the sidewall of a second semiconductor layer in the drain region.

In the present exemplary embodiment, the 3D memory may further comprise multiple bit lines extending along the first direction, two adjacent memory cells along the second direction being in a mirror image distribution, source regions of the transistors of the two adjacent memory cells being connected to one common bit line.

In the present exemplary embodiment, the 3D memory may further comprise multiple word lines extending along the third direction and arranged at intervals in the first direction, wherein the substrate is provided with the memory cell column in the third direction, and each word line is formed by connecting the gates in the transistors of one memory cell of one memory cell column arranged along the third direction.

Specifically, it can be applied to the DRAM field, which is a 3D memory cell formed by a super lattice structure.

Specifically, the multi-layer super lattice on the substrate may be used for forming multi-layer memory cells, each layer of memory cells may be memory cells distributed in an array, and the memory cells at the same position in the two-dimensional plane in each layer form a column of memory cells in the vertical direction, referred to as a memory cell column.

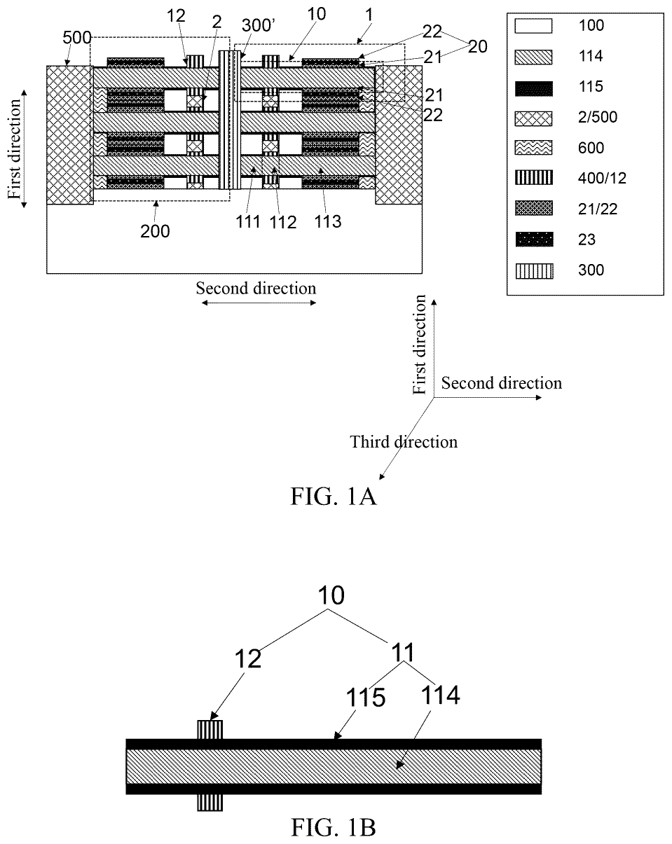

The present application will be illustrated below with two memory cell columns as examples. FIG. 1A is a schematic diagram of a main cross-sectional structure of a 3D memory according to an exemplary embodiment of the present disclosure in one direction and FIG. 1B is an enlarged diagram of a transistor of the 3D memory shown in FIG. 1A; FIG. 1C is an enlarged diagram of a capacitor of the 3D memory shown in FIG. 1A; FIG. 1D is a schematic diagram of a top structure of the 3D memory shown in FIG. 1A. As shown in FIGS. 1A through 1D, the 3D memory may comprise:

a substrate 100, multiple memory cell columns 200 formed of memory cells stacked and distributed in a direction perpendicular to the substrate (a first direction in FIG. 1A), and multiple bit lines 300 (Bit Line, BL) extending in the first direction, and two memory cell columns 200 in FIG. 1A sharing one bit line 300.

Multiple word lines 400 (WL) extend along a third direction in a plane parallel to an upper surface of the substrate, wherein FIG. 1A is a three-layer memory cell formed by a three-layer super lattice, each layer of memory cell corresponds to one word line 400, and a total of six word lines 400 are in FIG. 1A or FIG. 1B.

As shown in FIG. 1, each memory cell column 200 comprises multiple memory cells 1 disposed and stacked along the first direction at one side of the substrate 100, and the multiple memory cell columns 200 are arranged on the substrate 100 in a second direction and the third direction to form a multi-layer array, the second direction and the third direction intersecting and forming a plane parallel to a main plane of the substrate; the memory cell 1 comprises a transistor 10 and a capacitor 20 disposed in sequence along the second direction; the transistor 10 comprises a gate 12 and a semiconductor layer 11 that is strip-shaped and extends in a second direction, the strip-shaped semiconductor layer 11 has two ends and sidewalls, and on the sidewalls in the second direction, a source region 111, a channel region 112 and a drain region 113 are included in sequence, and the source region 111 and the drain region 113 are respectively adjacent to two ends of the semiconductor layer 11, the channel region 112 being located between the source region 111 and the drain region 113, the semiconductor layer comprising a first semiconductor layer 114 and a second semiconductor layer 115, the first semiconductor layer 114 is strip-shaped and has a sidewall, the first semiconductor layer 114 having a cross section of rectangular, circular, oval, etc. The second semiconductor layer 115 encircles the sidewalls of the first semiconductor layer 114, and the gate 12 encircles a sidewall of the second semiconductor layer 115 in the channel region 112; an electrode and a dielectric layer of the capacitor 20 encircle a sidewall of the second semiconductor layer 115 in the drain region 113.

In the present exemplary embodiment, as shown in FIG. 1A, the second semiconductor layer 115 may be cylindrical and disposed on the sidewall of the first semiconductor layer 114, for example, may be disposed on the outer wall of the first semiconductor layer 114, that is, the semiconductor layer may comprise the first semiconductor layer 114 and the cylindrical second semiconductor layer 115 disposed on the sidewall of the first semiconductor layer.

In the present exemplary embodiment, the first semiconductor layers in the source region 111, the channel region 112, and the drain region 113 are all encircled by the second semiconductor layer, and the second semiconductor layer at one end of the drain region 113 corresponding to the channel region 112 and the capacitor is not shown in the upper figure of

FIG. 1A, which is related to the selection of the cross-sectional position of the upper figure of FIG. 1A.

Every adjacent two memory cells along the second direction are regarded as one repeating unit as a whole. When there are 2n memory cells in the second direction, there are n repeating cells, and each repeating cell comprises two memory cells with mirror image symmetry in structure. In one repeating cell, two transistors are disposed adjacent to each other, capacitors on one semiconductor layer are disposed at both ends, a bit line 300 distributed in a vertical substrate direction are disposed between the two adjacent transistors, and transistors and capacitors in the two memory cells are mirror-symmetrically distributed about the bit line.

In the first direction, the source regions 111 of the transistors 10 of each of the memory cells 1 of two adjacent memory cell columns 200 are connected to the same bit line 300.

One or more memory cell columns 200 are disposed on the substrate 100 in the third direction; when the substrate 100 is provided with one memory cell column 200 in the third direction, each of the word lines 400 is formed by connecting the gates 12 of the transistors 10 of one memory cell 1 at respective layers of the one memory cell column 200 arranged in the third direction; alternatively, when the substrate 100 is provided with multiple memory cell columns 200 in the third direction, each of the word lines 400 is formed by connecting together the gates 12 of transistors 10 located in the same layer of multiple memory cells 1 arranged in the third direction.

In the description of the present disclosure, a “first direction” is defined as a direction perpendicular to the plane in which the substrate is located, i.e. a direction in which the height of the 3D memory is located; a “second direction” is defined as a direction perpendicular to the “first direction” and in which the width of the substrate is located; a “third direction” is defined as a direction perpendicular to the “first direction” and in which the length of the substrate is located; the second direction and the third direction intersect and form a plane parallel to the main plane of the substrate. The “first direction”, “second direction” and “third direction” may be shown in FIGS. 1A and 1D.

In the description of the present disclosure, each memory cell column is formed by multiple memory cells disposed and stacked on one side of the substrate in a first direction. The present disclosure takes one or more memory cells belonging to the same layer as a group, the group of memory cells being disposed and stacked in a direction perpendicular to the substrate, and memory cell groups of different stacks constitute columns extending in a direction perpendicular to the substrate.

The multiple groups constitute one array, that is to say, the memory cell groups of each layer constitute an array, or multiple columns formed by multiple stacked memory cell groups constitute an array. It can also be expressed that multiple memory cell columns are arranged in the second direction and the third direction to form an array.

The 3D memory of the embodiment of the present disclosure may employ a transverse semiconductor layer (i.e., a semiconductor layer extending along the second direction) and a transverse capacitor, so that the transistor and the capacitor may form a three-dimensional stacked structure, and memory cells formed by the transistor and the capacitor may be stacked together, increasing the storage density of the 3D memory; moreover, the sources of transistors of multiple memory cells in two adjacent memory cell columns in the second direction share one bit line, which may also reduce the size of the 3D memory and further increase the storage density of the 3D memory, thereby reducing the manufacturing cost per unit Gb, and providing a new technical research and development direction for the miniaturization bottleneck of the dynamic random access memory. In the embodiment of the present disclosure, the semiconductor layer 11 may be a semiconductor pillar.

In an embodiment of the present disclosure, one memory cell column may comprise 2 to 100 memory cells, for example, 2, 3 (as shown in FIGS. 1A and 1B), 4, 5, 10, 13, 15, 18, 20, 30, 40, 50, 60, 70, 80, 90, 100 memory cells.

In an embodiment of the present disclosure, the substrate may be provided with 2 to 1000 memory cell columns along the second direction, for example, 2 (as shown in FIGS. 1A and 1D), 4, 6, 8, 10, 12, 14, 16, 18, 20, 30, 40, 50, 60, 70, 80, 90, 100, 200, 300, 400, 500, 600, 700, 800, 900, 1000 memory cell columns; the substrate may be provided with 1 to 100 memory cell columns along the third direction, for example, 1, 2, 3 (as shown in FIGS. 1A and 1D), 4, 5, 12, 14, 16, 18, 20, 30, 40, 50, 60, 70, 80, 90, 100 memory cell columns.

In an embodiment of the present disclosure, the substrate may be a semiconductor substrate, for example, a monocrystalline silicon substrate, or a semiconductor on insulator (SOI) substrate, for example, a Silicon On Sapphire (SOS) substrate, a Silicon On Glass (SOG) substrate, an epitaxial layer of silicon based on a substrate semiconductor, or other semiconductor or photoelectric material, such as silicon-germanium (Si1-xGex, where x may be, for example, a mole fraction between 0.2 and 0.8), germanium (Ge), gallium arsenide (GaAs), gallium nitride (GaN), or indium phosphide (InP). The substrate may or may not be doped.

In an embodiment of the present disclosure, the lengths of the multiple word lines arranged at intervals along the first direction may be different, so that the multiple word lines arranged along the first direction and located at different layers may form a staircase shape.

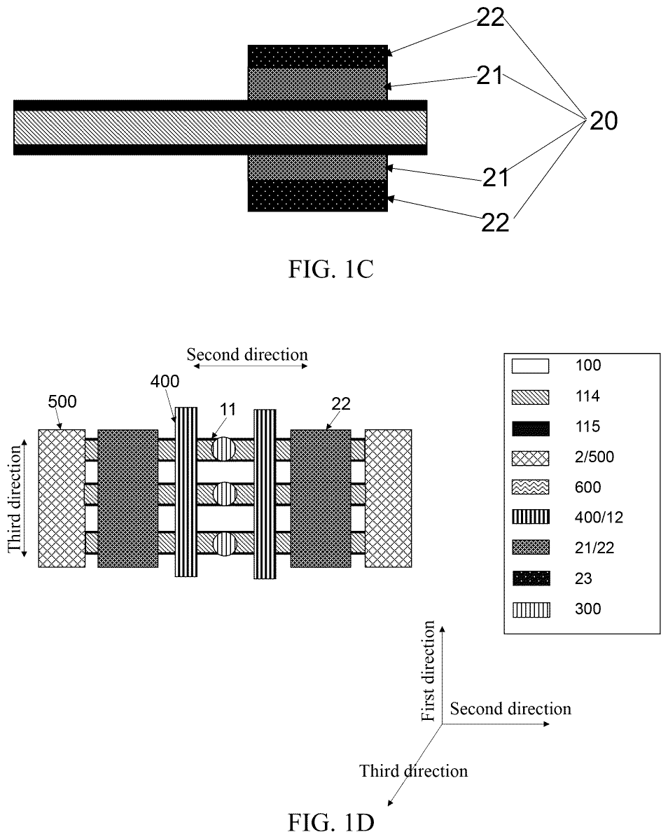

FIG. 2 is a distribution state diagram of multiple word lines arranged at intervals along the first direction in a side view direction of a 3D memory according to another exemplary embodiment of the present disclosure. As shown in FIG. 2, the multiple word lines 400 arranged at intervals along the first direction have different extension lengths in the third direction so that the multiple word lines 400 arranged along the first direction and located at different layers can be in the form of the staircase.

In an embodiment of the present disclosure, a material for the word line may be a material compatible with the semiconductor layer. For example, the material for the word line may comprise at least one of indium and tin, and for example, may be indium tin oxide (ITO) or the like.

In an embodiment of the present disclosure, a material for the bit line may be selected from any one or more of tungsten, molybdenum (Mo), cobalt (Co) and other metallic materials having similar properties.

In an embodiment of the present disclosure, the material for the first semiconductor layer may be selected from any one or more of Group IVA semiconductor materials, for example, may be single-crystal silicon.

In an embodiment of the present disclosure, the second semiconductor layer may be cylindrical or square cylindrical.

In an embodiment of the present disclosure, the material for the second semiconductor layer may be an oxide semiconductor material, for example, a metal oxide semiconductor material, the metal in the metal oxide may comprise at least one of indium, zinc, tungsten, tin, titanium, zirconium, hafnium, gallium, and for another example, the material for the second semiconductor layer may be selected from the group composed of Indium Gallium Zinc Oxide (IGZO), zinc stannate (ZTO), Indium Zinc Oxide (IZO), zinc oxide (ZnOx), indium tungsten oxide (InWO), Indium Zinc Tin Oxide (IZTO), Indium Zinc Tin Oxide (InOx, for example, In₂O₃), tin oxide (SnOx, For example, SnO2), titanium oxide (TiOx), zinc nitrogen oxide (ZnxOyNz), magnesium zinc oxide (MgxZnyOz), zirconium Indium Zinc Oxide (ZrxInyZnzOa), hafnium Indium Zinc Oxide (HfxInyZnzOa), aluminum tin Indium Zinc Oxide (AlxSnyInzZnaOd), silicon Indium Zinc Oxide (SixInyZnzOa), aluminum zinc tin oxide (AlxZnySnzOa), gallium zinc tin oxide (GaxZnySnzOa), zirconium zinc tin oxide (ZrxZnySnzOa) and indium gallium silicon oxide (InGaSiOx).

The semiconductor layer adopts a double-layer structure formed by a first semiconductor layer and a second semiconductor layer. An oxide semiconductor thin film can be grown on a single crystal of the first semiconductor layer (for example, monocrystalline silicon) as the second semiconductor layer, and the characteristic of the oxide semiconductor thin film with minimal leakage can be fully utilized, thereby increasing the switching ratio of the memory equipment.

In an embodiment of the present disclosure, the thickness of the second semiconductor layer may be 5 nm to 15 nm.

In an embodiment of the present disclosure the height of the semiconductor layer in the first direction may be set according to actual electrical requirements for example may be 10 nm to 50 nm.

In the embodiment of the present disclosure, as shown in FIGS. 1A and 1C, the capacitor 20 may comprise a first electrode plate 21, a second electrode plate 22 (both of which belong to electrodes of the capacitor), a dielectric layer 23 disposed between the first electrode plate 21 and the second electrode plate 22, and a second semiconductor layer 115 of the drain region 113 connected to the first electrode plate 21. As shown in FIG. 1D, the outer electrode plates 22 of the multiple capacitors 20 arranged in the third direction may be connected together but the first electrode plates 21 thereof are separated.

In an embodiment of the present disclosure, the first electrode plate may be an inner electrode plate and the second electrode plate may be an outer electrode plate.

In the embodiment of the present disclosure as shown in FIGS. 1A and 1B, one transistor 10 may correspond to one capacitor 20 i.e. the memory cell 1 may be of a 1TIC structure.

In an embodiment of the present disclosure, two capacitors adjacent in the first direction may share one second electrode plate.

In an embodiment of the present disclosure, the materials for the first electrode plate and the second electrode plate each may be independently selected from any one or more of other metal materials having similar properties such as titanium nitride (TiN), titanium aluminum (TiAl), tantalum nitride (TaN), etc. The thickness of the first electrode plate may be 5 nm to 15 nm, and the thickness of the second electrode plate may be 5 nm to 15 nm.

In an embodiment of the present disclosure, the material for the dielectric layer may be a high dielectric constant (K) material, for example, may be selected from any one or more of hafnium dioxide (HfO₂), alumina (Al₂O₃), zirconia ZrO, and strontium titanate (SrTiO₃, STO). The dielectric layer may have a thickness ranging from 5 nm to 15 nm.

In an embodiment of the present disclosure, as shown in FIGS. 1A and 1D, the memory cell column 200 may further comprise an interlayer isolation layer 2 disposed between gates 12 of transistors 10 of two adjacent memory cells 1 in the memory cell column 200 to isolate the gates 12 of transistors 10 of two adjacent memory cells 1.

In an embodiment of the present disclosure, the material for the interlayer isolation layer may be silicon oxide, for example, SiO₂.

In an embodiment of the present disclosure, the interlayer isolation layer may be an interlayer isolation belt.

In an embodiment of the present disclosure, the transistor may also comprise a gate dielectric layer (also called a gate insulating layer, not shown) disposed between the channel region and the gate.

In an embodiment of the present disclosure, the material for the gate dielectric layer may be selected from any one or more of silicon dioxide, hafnium dioxide (HfO₂), alumina (Al₂O₃), zirconia ZrO.

In an embodiment of the present disclosure the thickness of the gate dielectric layer may be set according to actual electrical requirements for example may be 2 nm to 5 nm.

In an embodiment of the present disclosure, the material for the gate may be selected from any one or more of ITO or other low-temperature semiconductor materials.

In an embodiment of the present disclosure as shown in FIGS. 1A and 1D the 3D memory may further comprise one or more memory cell isolation pillars 500 extending in the first direction. For example one of the memory cell isolation pillars 500 may be provided at intervals of two memory cell columns 200 in the second direction.

In an embodiment of the present disclosure, the material for the memory cell isolation pillar may be silicon oxide, for example, may be selected from any one or more of a Spin-On Deposition (SOD) silicon oxide film, a High Density Plasma (HDP) silicon oxide film, and a High Aspect Ratio Process (HARP) silicon oxide film.

In the embodiment of the present disclosure, as shown in FIG. 1A, the 3D memory may further comprise an internal support layer 600 disposed between two semiconductor layers 11 adjacent in the first direction and configured to provide support to the semiconductor layer 11.

In an embodiment of the present disclosure as shown in FIG. 1A the internal support layer 600 may also be located on both sides of the memory cell isolation pillar 500. The semiconductor layer 11 can be firmly supported when the internal support layer 600 is provided on both sides of the memory cell isolation pillar 500.

In an embodiment of the present disclosure, the material for the inner support layer may be a thin film material having a supporting effect, for example, SiN.

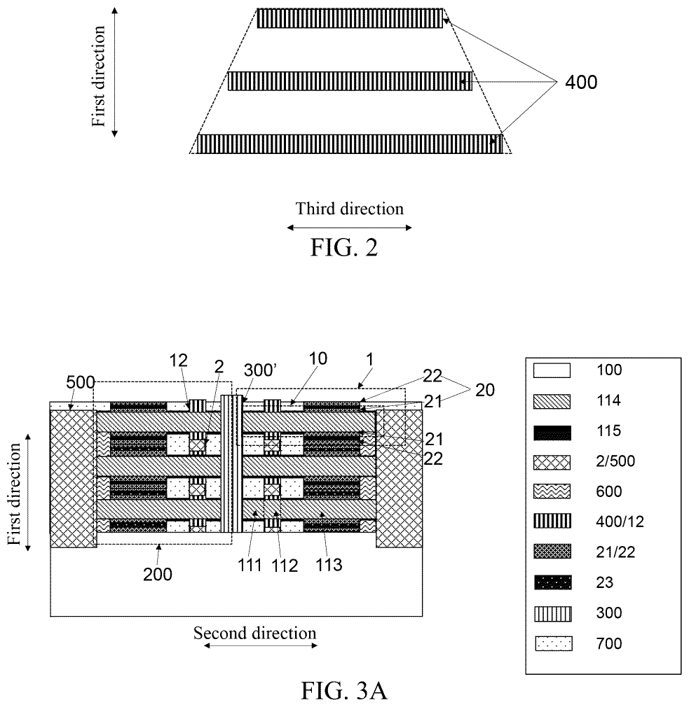

FIG. 3A is a main cross-sectional structural diagram in one direction of the 3D memory of another exemplary embodiment of the present disclosure, and FIG. 3B is a top view structural diagram of the 3D memory shown in FIG. 3A. As shown in FIGS. 3A and 3B in an exemplary embodiment of the present disclosure, a blank space between the semiconductor layer the bit line and the word line may be filled with an isolation material 700.

In an embodiment of the present disclosure, the isolation material may be selected from any one or more of a SOD silicon oxide film, an HDP silicon oxide film, and a HARP silicon oxide film.

Embodiments of the present disclosure also provide a memory comprising:

Multiple repeating units distributed in an array, and every two adjacent repeating units are isolated by isolation pillars; wherein the repeating unit comprises at least one layer of memory cell, and each layer of the repeating unit comprises a first memory cell and a second memory cell located between the two isolation pillars; wherein the two memory cells comprise a first transistor and a second transistor;
one or multiple transversely extending semiconductor pillars are disposed between the two isolation pillars, and the plurality of transversely extending semiconductor pillars are distributed at intervals along a direction perpendicular to the substrate;
the semiconductor pillar has sidewalls and two ends positioned in the isolation pillar such that the semiconductor pillar is supported by the isolation pillar.

A first ring-shaped semiconductor layer (e.g. a first semiconductor layer in the 3D memory provided by the embodiment of the present application) and a second ring-shaped semiconductor layer (e.g. a second semiconductor layer in the 3D memory provided by the embodiment of the present application) are transversely distributed at intervals in different regions of the sidewalls of the semiconductor pillar. The first ring-shaped semiconductor layer and the second ring-shaped semiconductor layer are wrapped with a first gate and a second gate disposed at intervals, respectively, wherein the first gate is insulated from the first ring-shaped semiconductor layer through an insulating layer, and the second gate is insulated from the second ring-shaped semiconductor layer through an insulating layer.

The memory further comprises a first capacitor and a second capacitor transversely distributed at intervals in different regions of the sidewalls of the semiconductor pillar; the first memory cell comprises the first capacitor and the first transistor, and the second memory cell comprises the second capacitor and the second transistor.

The first capacitance electrode of the first capacitor and the second capacitance electrode of the second capacitor wrap different regions of the sidewall of the semiconductor pillar, respectively.

The first capacitor, the first transistor, the second transistor and the second capacitor are transversely distributed at intervals in sequence. The embodiment of the disclosure also provides a manufacturing method of the memory. As described above, the memory provided by the embodiment of the present disclosure (comprising the 3D memory provided by the embodiment of the present disclosure) can be obtained by the manufacturing method.

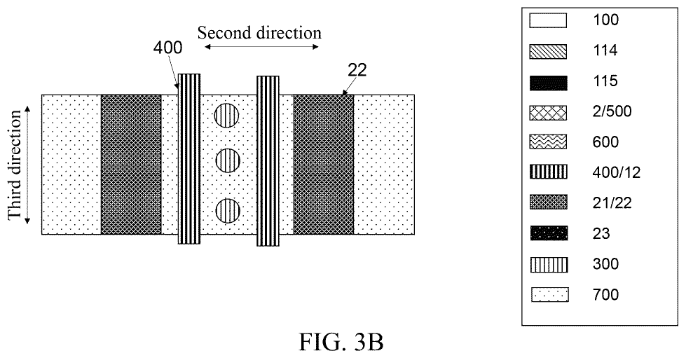

FIG. 4 is a process flow diagram of a manufacturing method of a memory according to an embodiment of the present disclosure. As shown in FIG. 4, the manufacturing method may comprise:

S10: stacking and disposing multiple epitaxial layers composed of a sacrificial layer and a first initial semiconductor layer on one side of substrate along a first direction in an order of the sacrificial layer and the first initial semiconductor layer;

S20: defining a memory cell region in the multiple epitaxial layers, etching a memory cell isolation groove along the first direction, and filling a memory cell isolation pillar in the memory cell isolation groove;

S30: removing the sacrificial layer, the remaining first initial semiconductor layer forming a first semiconductor layer, providing a cylindrical second semiconductor layer on a sidewall of the first semiconductor layer, the first semiconductor layer and the second semiconductor layer form multiple strip-shaped semiconductor layers arranged in an array along the first direction and the third direction and extending along the second direction, the semiconductor layer comprising a source region and a drain region located at two ends in the second direction, and a channel region located between the source region and the drain region;

S40: setting a gate of the second semiconductor layer encircling the channel region on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, there are multiple semiconductor layers arranged in the third direction, so that gates on the plurality of semiconductor layers arranged in the third direction are connected together in the third direction to form word lines;

S50: providing a capacitor encircling one end of the second semiconductor layer of the drain region on a sidewall of one end, away from the channel region, of the second semiconductor layer in the drain region of the semiconductor layer, an electrode and a dielectric layer of the capacitor both encircling on the sidewall of the second semiconductor layer in the drain region;

S60: the bit line trench penetrating through the semiconductor layer being provided in bit line regions of the plurality of semiconductor layers arranged in the first direction, bit line materials filled in the bit line trench and between the bit line trenches of the plurality of semiconductor layers arranged in the first direction, a bit line extending in the first direction being formed, and the bit lines being connected with the source regions of the plurality of semiconductor layers in contact with the bit line so that the source regions of the plurality of semiconductor layers share one bit line.

In an embodiment of the present disclosure, step S20 may comprise:
S21: defining a memory cell region in the multiple epitaxial layers and etching a memory cell isolation groove along a first direction;
S22: carrying out side etching on the part of the memory cell isolation groove corresponding to the sacrificial layer along the second direction to obtain an internal support groove, and filling the internal support layer in the internal support groove;
S23: filling a memory cell isolation pillar in the memory cell isolation groove.

In an embodiment of the present disclosure, step S40 may comprise:
S41: a gate dielectric layer and a gate encircling the second semiconductor layer in the channel region sequentially disposed on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, there are multiple semiconductor layers arranged in the third direction, so that gates on the plurality of semiconductor layers arranged in the third direction are connected together in the third direction to form word lines;
Optionally, S42: setting the extension lengths of the multiple word lines, arranged in the first direction, in the third direction to be different, so that the multiple word lines arranged in the first direction at different layers present a staircase shape;
Optionally, S43: an interlayer isolation layer provided between two semiconductor layers adjacent in the first direction, thereby isolating gates on the two semiconductor layers adjacent in the first direction.

For example, in an exemplary embodiment of the present disclosure, i) step S40 may comprise:
S41: a gate dielectric layer and a gate encircling the second semiconductor layer of the channel region are sequentially disposed on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, there are multiple semiconductor layers arranged in the third direction, so that gates on the plurality of semiconductor layers arranged in the third direction are connected together in the third direction to form word lines.

Alternatively, ii) step S40 may comprise:
S41: a gate dielectric layer and a gate encircling the second semiconductor layer of the channel region are sequentially disposed on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, there are multiple semiconductor layers arranged in the third direction, so that gates on the plurality of semiconductor layers arranged in the third direction are connected together in the third direction to form word lines;
S42: the extension lengths of the plurality of word lines, arranged in the first direction, in the third direction are set to be different, so that the plurality of word lines arranged in different layers along the first direction present a staircase shape.

Alternatively, iii) Step S40 may comprise:
S41: a gate dielectric layer and a gate encircling the second semiconductor layer of the channel region sequentially disposed on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, multiple semiconductor layers arranged in the third direction, so that gates on the plurality of semiconductor layers arranged in the third direction are connected together in the third direction to form word lines;
S43: setting an interlayer isolation layer between two semiconductor layers adjacent in the first direction, so as to isolate gates on the two semiconductor layers adjacent in the first direction.

Alternatively, iiii) Step S40 may comprise:
S41: a gate dielectric layer and a gate encircling the second semiconductor layer of the channel region are sequentially disposed on a sidewall of the second semiconductor layer of the channel region of the semiconductor layer, to obtain multiple transistors formed by the semiconductor layer and the gate; and one semiconductor layer arranged in the third direction, so that the gate on this semiconductor layer serves as a word line; alternatively, there are multiple semiconductor layers arranged in the third direction, so that gates on the plurality of semiconductor layers arranged in the third direction are connected together in the third direction to form word lines;
S42: the extension lengths of the plurality of word lines, arranged in the first direction, in the third direction are set to be different, so that the plurality of word lines arranged in different layers along the first direction present a staircase shape;
S43: an interlayer isolation layer is provided between two semiconductor layers adjacent in the first direction, so as to isolate gates on the two semiconductor layers adjacent in the first direction.

In an embodiment of the present disclosure, step S50 may comprise sequentially disposing a first electrode plate, a dielectric layer, and a second electrode plate encircling one end of the second semiconductor layer of the drain region on a sidewall of one end, away from the channel region, of a second semiconductor layer of the drain region of the semiconductor layer, to obtain a capacitor encircling one end of the second semiconductor layer of the drain region.

In the embodiment of the present disclosure, the manufacturing method further comprises: after step S60,

S70: an isolation material is filled in a blank space between the semiconductor layer, the bit line, and the word line.

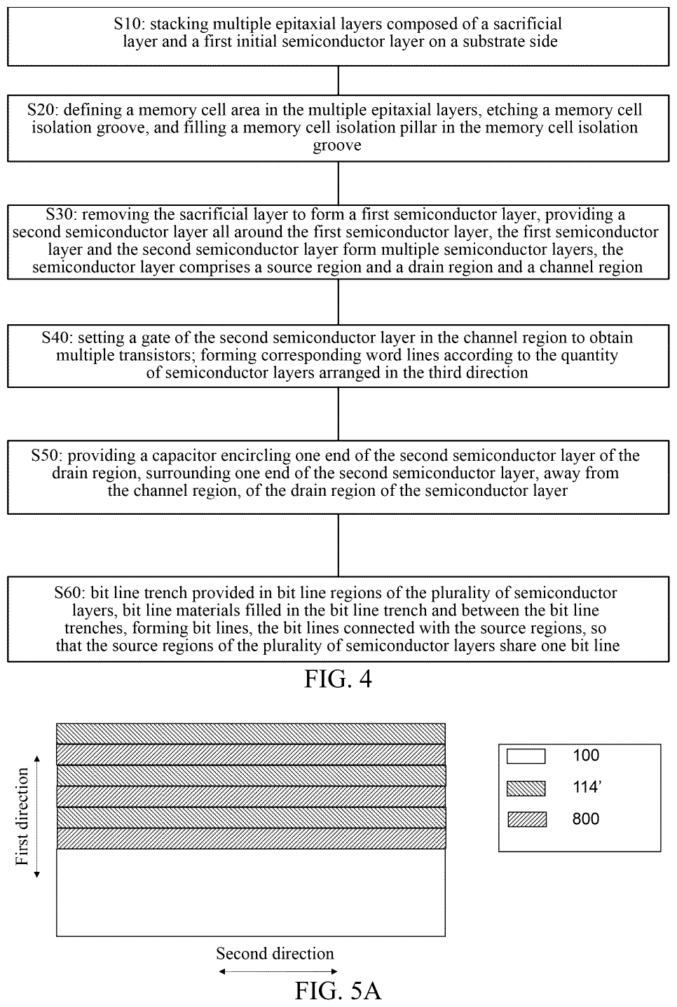

FIGS. 5A to 9B are main sectional structural diagrams and top structural diagrams of intermediate articles obtained by intermediate steps of the manufacturing method of the memory of the exemplary embodiment of the present disclosure. As shown in FIGS. 5A to 9B, in an exemplary embodiment, the manufacturing method of the memory may comprise:

S10: multiple epitaxial layers composed of the sacrificial layer 800 and the first initial semiconductor layer 114′ are disposed and stacked in a first direction in the order of the sacrificial layer 800 and the first initial semiconductor layer 114′ on one side of the substrate 100, to obtain an intermediate product as shown in FIGS. 5A and 5B;

S21: defining a memory cell region l′ in multiple epitaxial layers and etching and obtaining a memory cell isolation groove 500′ in a first direction;

S22: performing a side etching on a portion of the memory cell isolation groove 500′ corresponding to the sacrificial layer 800 in a second direction, to obtain an internal support groove 600′, and filling the internal support layer 600 in the internal support groove 600′;

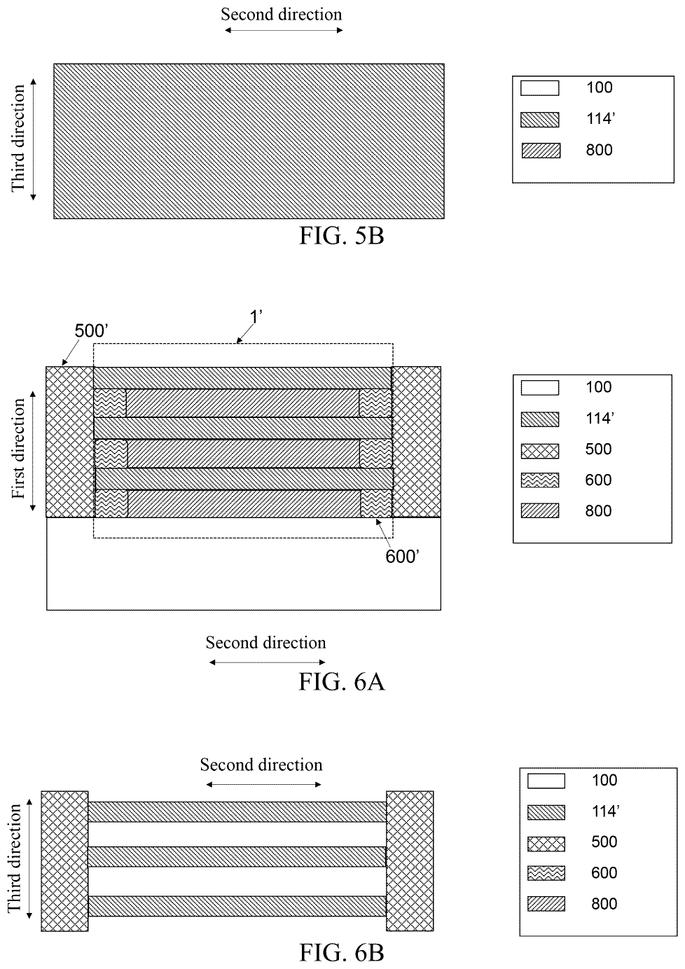

S23: filling a memory cell isolation pillar 500 in the memory cell isolation groove 500′ to obtain an intermediate product as shown in FIGS. 6A and 6B;

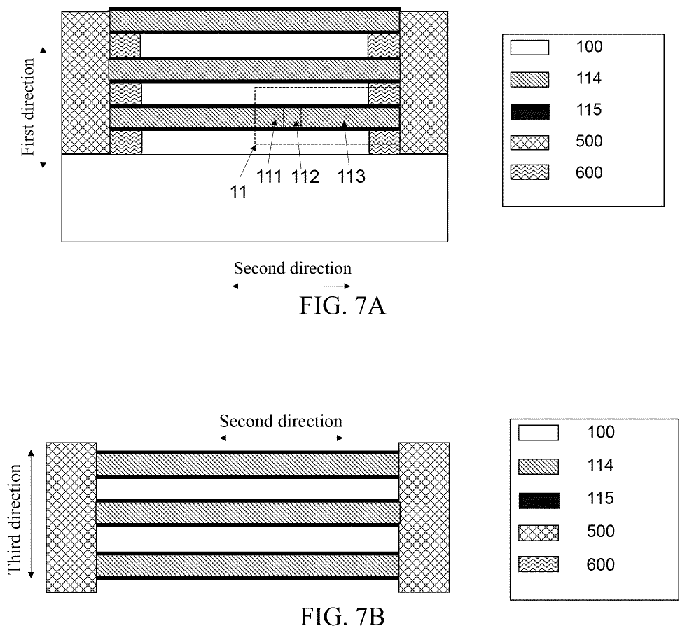

S30: removing the sacrificial layer 800, the remaining first initial semiconductor layer 114′ forming a first semiconductor layer 114, providing a cylindrical second semiconductor layer 115 on a sidewall of the first semiconductor layer 114, the first semiconductor layer 114 and the second semiconductor layer 115 forming multiple semiconductor layers 11 arranged in an array along a first direction and a third direction and extending along the second direction, the semiconductor layer 11 comprising a source region 111 and a drain region 113 located at two ends in the second direction, and a channel region 112 being located between the source region 111 and the drain region 113 in the second direction, to obtain an intermediate product as shown in FIGS. 7A and 7B;

S41: sequentially providing a gate dielectric layer (not shown) and a gate 12 encircling the second semiconductor layer 115 of the channel region 112 on the sidewall of the second semiconductor layer 115 of the channel region 112 of the semiconductor layer 11, to obtain multiple transistors 10 formed of the semiconductor layer 11 and the gate 12; and one semiconductor layer 11 arranged in the third direction, so that a gate 12 on the semiconductor layer 11 serves as a word line 400; alternatively, multiple semiconductor layers 11 arranged in the third direction, so that the gates 12 on the plurality of semiconductor layers 11 arranged in the third direction are connected together in the third direction to form a word line 400;

S42: setting different extension lengths of the multiple word lines 400, arranged in the first direction, in the third direction, so that the plurality of word lines 400 arranged in different layers along the first direction present a staircase shape;

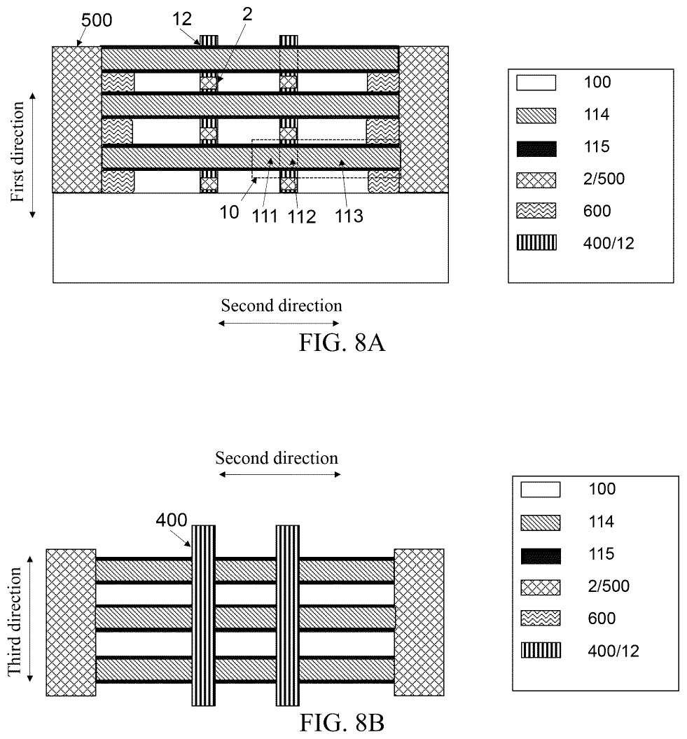

S43: providing an interlayer isolation layer 2 between two semiconductor layers 11 adjacent in the first direction, so as to isolate the gates 12 on the two semiconductor layers 11 adjacent in the first direction, to obtain an intermediate product as shown in FIGS. 8A and 8B;

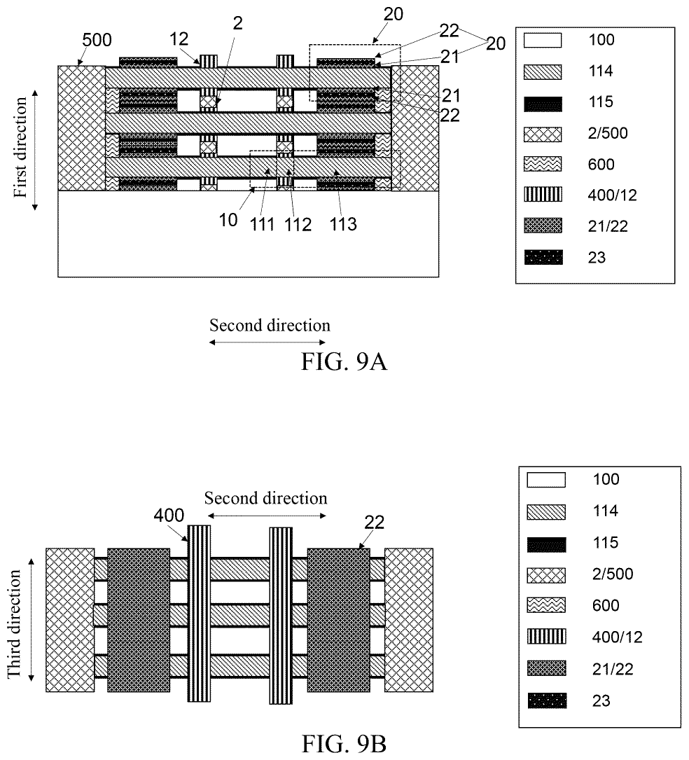

S50: a first electrode plate 21, a dielectric layer 23, and a second electrode plate 22 encircling one end of the second semiconductor layer 115 of the drain region 113 of the semiconductor layer 11 sequentially provided on a sidewall at one end of the second semiconductor layer 115, away from the channel region 112, of the drain region 113 of the semiconductor layer 11, thereby obtaining a capacitor 20 encircling one end of the second semiconductor layer 115 of the drain region 113 and obtaining an intermediate product as shown in FIGS. 9A and 9B;

S60: a bit line trench 300′ penetrating through the semiconductor layer 11 provided in bit line regions of the plurality of semiconductor layers 11 arranged in a first direction, bit line materials filled in the bit line trench 300′ and between the bit line trenches of the multiple semiconductor layers 11 arranged in the first direction, a bit line 300 extending in the first direction being formed, the bit line 300 connected with the source regions 111 of the plurality of semiconductor layers 11 in contact with the bit line 300, so that the source regions 111 of the plurality of semiconductor layers 11 share one bit line 300, and a 3D memory shown in FIGS. 1A to 1D is obtained;

S70: filling an isolation material 700 in a blank space between the semiconductor layer 11, the bit line 300, and the word line 400 to obtain a 3D memory as shown in FIGS. 3A and 3B.

In an embodiment of the present disclosure, the material for the sacrificial layer may be any one or more of other conductive materials having similar properties such as SiGe. The thickness of the sacrificial layer may be 30 nm to 50 nm, for example, 30 nm, 35 nm, 40 nm, 45 nm, 50 nm.

In the embodiment of the present disclosure, in step S10, a super lattice thin film stack layer of the sacrificial layer/the first initial semiconductor layer can be grown on the substrate by an epitaxial device, to obtain multiple epitaxial layers composed of the sacrificial layer and the first initial semiconductor layer.

In the embodiment of the present disclosure, in step S21, patterning etching can be carried out by illumination exposure using the same layer of a photo mask to form grooves arranged in the third direction and extending in the second direction, so as to isolate multiple sacrificial layers/first initial semiconductor layers in the third direction and obtain a memory cell region.

In the embodiment of the present disclosure, the memory cell isolation groove can be obtained by Reactive-Ion Etch (RIE) in step S21.

In the embodiment of the present disclosure, in step S22, a portion of the memory cell isolation groove corresponding to the sacrificial layer may be side-etched by wet etching.

In the embodiment of the present disclosure, in step S22, the internal support layer may be filled in the internal support layer trench by an Atomic layer deposition (ALD) process or a Chemical Vapor Deposition (CVD) process, for example, SiN may be filled in the internal support layer trench by an ALD process to form the internal support layer.

In the embodiment of the present disclosure, a memory cell isolation pillar may be filled in the memory cell isolation groove by a SOD, HDP or HARP process in step S23, for example, a silicon oxide film may be filled in the memory cell isolation groove by a SOD, HDP or HARP process to form the memory cell isolation pillar.

In the embodiment of the present disclosure, the sacrificial layer may be etched away while the first initial semiconductor layer is retained by selecting the ultra-high sacrificial layer/first initial semiconductor layer etching ratio in step S30 by an etching method, which may be dry etching or wet etching.

In the embodiment of the present disclosure, a cylindrical second semiconductor layer may be provided on the sidewall of the first semiconductor layer by an ALD process in step S30.

In the embodiment of the present disclosure step S42 can be obtained by trim etch (staircase WL).

In the embodiment of the present disclosure, the interlayer isolation layer may be provided by an ALD or Chemical Vapor Deposition (CVD) process in step S43, for example, SiO₂ may be filled by an ALD or CVD process to form the interlayer isolation layer.

In the embodiment of the present disclosure, the isolation material may be filled in the blank space by the SOD, HDP or HARP process in step S70, for example, any one or more of the SOD silicon oxide film, the HDP silicon oxide film and the HARP silicon oxide film may be formed in the blank space by the SOD, HDP or HARP process.

Embodiments of the present disclosure also provide a dynamic random access memory (DRAM), comprising the 3D memory as provided in the embodiment of the present application, or comprising the memory as provided in the embodiment of the present application.

Embodiments of the present disclosure also provide an electronic device comprising a dynamic random access memory as described above.

In an embodiment of the present disclosure, the electronic device may comprise a storage apparatus, a smart phone, a computer, a tablet computer, an artificial intelligence device, a wearable device, or a mobile power supply.

In the description in the present disclosure, it should be noted that the terms “up”, “down”, “side”, “other side”, “one end”, “other end” and the like denote an orientation or positional relationship based on those shown in the drawings, are intended for ease of description and simplification of the description only, and are not intended to indicate or imply that the structure referred to has a particular orientation, is constructed and operates in a particular orientation, and therefore cannot be construed as limiting to the present disclosure.

In the description of embodiments of the present disclosure, the terms “connected”, “arranged” are to be understood broadly, for example, as a fixed connection, a detachable connection, or an integral connection, unless otherwise expressly specified and limited; The terms “connection” and “setting” can be directly connected or indirectly connected through an intermediate medium, and can be internal communication between two components. For those of ordinary skill in the art, the meaning of the above terms in the present disclosure may be understood according to actual situation.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure belongs may make any modifications and changes in the form and details of implementation, but the scope of patent protection of the present disclosure shall still be defined by the appended claims.

1. A memory comprising:
a substrate;
a plurality of memory cell columns distributed in a first direction perpendicular to the substrate, each of the memory cell columns comprising a plurality of memory cells disposed and stacked along the first direction, different memory cell columns being arranged on the substrate along a second direction and a third direction to form an array; the second direction and the third direction being intersected and the formed plane being parallel to a main plane of the substrate;
the memory cell comprising a transistor and a capacitor disposed in sequence along the second direction, the transistor comprising a semiconductor layer and a gate, the semiconductor layer extending as a strip structure along the second direction, the strip structure having sidewalls and both ends, and the sidewall in the second direction comprising a source region, a channel region and a drain region, the source region and the drain region being adjacent to two ends of the semiconductor layer, respectively, the channel region being located between the source region and the drain region, the semiconductor layer comprising a first semiconductor layer and a cylindrical second semiconductor layer disposed on sidewalls of the first semiconductor layer, and the gate encircling sidewalls of the second semiconductor layer in the channel region; an electrode and a dielectric layer of the capacitor encircling the sidewall of the second semiconductor layer in the drain region.

2. The memory according to claim 1, further comprising: a plurality of bit lines extending along the first direction, two adjacent memory cells along the second direction being in a mirror image distribution, source regions of transistors of the two adjacent memory cells being connected to one common bit line.

3. The memory according to claim 1, further comprising: a plurality of word lines extending along the third direction and arranged at intervals in the first direction, wherein the substrate is provided with one memory cell column in the third direction, and each word line is formed by connecting gates in transistors of one memory cell of one memory cell column arranged along the third direction.

4. The memory according to claim 3, wherein the plurality of word lines arranged at intervals in the first direction have different lengths and form a staircase shape.

5. The memory according to claim 4, wherein, a material for the word line comprises at least one of indium and tin.

6. The memory according to claim 1, wherein a material for the first semiconductor layer is selected from any one or more of Group IVA semiconductor materials.

7. The memory according to claim 6, wherein the material for the first semiconductor layer is single-crystal silicon.

8. The memory according to claim 7, wherein a material for the second semiconductor layer is a metal oxide semiconductor material, and metals in the metal oxide comprise at least one of indium, zinc, tungsten, tin, titanium, zirconium, hafnium and gallium.

9. The memory according to claim 1, wherein the memory cell column further comprises an interlayer isolation layer disposed between gates of transistors of two adjacent memory cells in the memory cell column to isolate the gates of the transistors of the two adjacent memory cells.

10. The memory according to claim 1, further comprising one or more memory cell isolation pillars extending along the first direction, and one memory cell isolation pillar being provided every two memory cell columns in the second direction.

11. The memory according to claim 10, wherein a material for the memory cell isolation pillar is silicon oxide.

12. The memory according to claim 10, further comprising an internal support layer disposed between two adjacent semiconductor layers along the first direction and configured to provide support to the semiconductor layers.

13. The memory according to claim 12, wherein the internal support layer is located on a sidewall of the memory cell isolation pillar.

14. The memory according to claim 13, wherein a material for the internal support layer is silicon nitride.

15. A memory comprising:
a plurality of repeating units distributed in an array, and every two adjacent repeating units being isolated by an isolation pillar; wherein the repeating unit comprises at least one layer of memory cell, and each layer of the repeating unit comprises a first memory cell and a second memory cell located between the two isolation pillars; wherein the two memory cells comprise a first transistor and a second transistor;
one or a plurality of transversely extending semiconductor pillars being disposed between the two isolation pillars, and the plurality of transversely extending semiconductor pillars being distributed at intervals along a direction perpendicular to a substrate;
the semiconductor pillar having sidewalls and two ends positioned in the isolation pillar such that the semiconductor pillar is supported by the isolation pillar;
a first ring-shaped semiconductor layer and a second ring-shaped semiconductor layer being distributed at intervals in a transverse direction in different regions of the sidewalls of the semiconductor pillar; the first ring-shaped semiconductor layer and the second ring-shaped semiconductor layer being wrapped with a first gate and a second gate disposed at intervals, respectively, wherein the first gate is insulated from the first ring-shaped semiconductor layer through an insulating layer, and the second gate is insulated from the second ring-shaped semiconductor layer through the insulating layer;
wherein the memory further comprises a first capacitor and a second capacitor transversely distributed at intervals in different regions of the sidewalls of the semiconductor pillar; the first memory cell comprises the first capacitor and the first transistor, and the second memory cell comprises the second capacitor and the second transistor;
a first capacitance electrode of the first capacitor and a second capacitance electrode of the second capacitor wrap different regions of the sidewalls of the semiconductor pillar, respectively;
wherein the first capacitor, the first transistor, the second transistor and the second capacitor are transversely distributed at intervals in sequence.

16. A dynamic random access memory comprising a memory according to claim 15.

17. An electronic device comprising a dynamic random access memory according to claim 16.

18. The electronic device according to claim 17, comprising a storage apparatus, a smart phone, a computer, a tablet, an artificial intelligence device, a wearable device, or a mobile power supply.
